(19) United States
(12) Patent Application Publication
(10) Pub. No.: US 2016/0172401 A1
(43) Pub. Date: Jun. 16, 2016

(54) SOLID-STATE IMAGING DEVICE, CAMERA MODULE, AND METHOD FOR MANUFACTURING SOLID-STATE IMAGING DEVICE

(71) Applicant: Kabushiki Kaisha Toshiba, Minato-ku (JP)

(72) Inventors: Atsuko KAWASAKI, Yokohama (JP); Soichiro Ueno, Koto (JP)

(73) Assignee: Kabushiki Kaisha Toshiba, Minato-ku (JP)

(21) Appl. No.: 14/958,214

(22) Filed: Dec. 3, 2015

(30) Foreign Application Priority Data
Dec. 11, 2014 (JP) 2014-250802

(51) Int. Cl. H01L 27/146; H04N 5/335; H04N 5/363; H04N 5/225

(52) U.S. Cl. CPC H01L 27/14627; H04N 5/2254; H04N 5/2257; H04N 5/335; H04N 5/363; H01L 27/14685; H01L 27/14623

(57) ABSTRACT

Certain embodiments provide a solid-state imaging device including a sensor substrate including a microlens, a transparent resin layer provided so as to be in contact with a main surface of the sensor substrate including a surface of the microlens, and a transparent substrate disposed on a top surface of the transparent resin layer. A thermal conductivity of the transparent resin layer is higher than that of air, and a refractive index of the transparent resin layer is lower than that of the microlens and is equal to or lower than that of the transparent substrate.

### CROSS REFERENCE TO RELATED APPLICATIONS

This application is based upon and claims the benefit of priority from the prior Japanese Patent Application No. 2014-250802 filed in Japan on Dec. 11, 2014; the entire contents of which are incorporated herein by reference.

### FIELD

Embodiments described herein relate generally to a solid-state imaging device, a camera module, and a method for manufacturing a solid-state imaging device.

### BACKGROUND

In the related art, a solid-state imaging device includes a sensor substrate including light-receiving units, an adhesive which is formed on the sensor substrate in peripheries of the light-receiving unit, and a glass substrate which is disposed on the adhesive. In the solid-state imaging device, a space surrounded by the adhesive is formed between the light-receiving unit and the glass substrate.

Since the space is filled with air having a very low thermal conductivity, the space hardly becomes a heat dissipation path for the heat generated from the sensor substrate. Therefore, the solid-state imaging device in the related art has problems in that a heat dissipation property there is poor and the space between the light-receiving units is filled with heat. As a result, noise originated from the heat is generated, and imaging characteristics of the solid-state imaging device are deteriorated.

Furthermore, the light incident on the solid-state imaging device passes through a glass substrate and air to reach the light-receiving unit of the sensor substrate. However, reflection of the light cannot be avoided on the interface between the glass substrate and the air, and a deterioration in sensitivity of the solid-state imaging device caused by the reflection of the light cannot be avoided. Like this, a deterioration in imaging characteristics of the solid-state imaging device is caused by the reflection of the incident light.

### BRIEF DESCRIPTION OF THE DRAWINGS

FIG. 1 is a cross-sectional diagram illustrating a solid-state imaging device according to a first embodiment;

FIG. 2A is a cross-sectional diagram illustrating a method of manufacturing the solid-state imaging device according to the first embodiment and corresponding to FIG. 1;

FIG. 2B is a cross-sectional diagram illustrating the method of manufacturing the solid-state imaging device according to the first embodiment and corresponding to FIG. 1;

FIG. 2C is a cross-sectional diagram illustrating the method of manufacturing the solid-state imaging device according to the first embodiment and corresponding to FIG. 1;

FIG. 2D is a cross-sectional diagram illustrating the method of manufacturing the solid-state imaging device according to the first embodiment and corresponding to FIG. 1;

FIG. 3 is a cross-sectional diagram illustrating a heat dissipation function of the solid-state imaging device according to the first embodiment and corresponding to FIG. 1;

FIG. 4 is a cross-sectional diagram illustrating a solid-state imaging device according to a second embodiment;

FIG. 5A is a cross-sectional diagram illustrating the method of manufacturing the solid-state imaging device according to the second embodiment and corresponding to FIG. 4;

FIG. 5B is a cross-sectional diagram illustrating the method of manufacturing the solid-state imaging device according to the second embodiment and corresponding to FIG. 4;

FIG. 5C is a cross-sectional diagram illustrating the method of manufacturing the solid-state imaging device according to the second embodiment and corresponding to FIG. 4;

FIG. 5D is a cross-sectional diagram illustrating the method of manufacturing the solid-state imaging device according to the second embodiment and corresponding to FIG. 4;

FIG. 6 is a cross-sectional diagram illustrating a solid-state imaging device according to a third embodiment;

FIG. 7A is a cross-sectional diagram illustrating a method of manufacturing the solid-state imaging device according to the third embodiment and corresponding to FIG. 6;

FIG. 7B is a cross-sectional diagram illustrating the method of manufacturing the solid-state imaging device according to the third embodiment and corresponding to FIG. 6;

FIG. 8 is a cross-sectional diagram illustrating a solid-state imaging device according to a fourth embodiment;

FIG. 9A is a cross-sectional diagram illustrating the method of manufacturing the solid-state imaging device according to the fourth embodiment and corresponding to FIG. 8;

FIG. 9B is a cross-sectional diagram illustrating the method of manufacturing the solid-state imaging device according to the fourth embodiment and corresponding to FIG. 8;

FIG. 10 is a cross-sectional diagram illustrating a solid-state imaging device according to a fifth embodiment;

FIG. 11A is a cross-sectional diagram illustrating the method of manufacturing the solid-state imaging device according to the fifth embodiment and corresponding to FIG. 10;

FIG. 11B is a cross-sectional diagram illustrating the method of manufacturing the solid-state imaging device according to the fifth embodiment and corresponding to FIG. 10;

FIG. 11C is a cross-sectional diagram illustrating the method of manufacturing the solid-state imaging device according to the fifth embodiment and corresponding to FIG. 10;

FIG. 12 is a cross-sectional diagram illustrating a solid-state imaging device according to a sixth embodiment;

FIG. 13A is a cross-sectional diagram illustrating the method of manufacturing the solid-state imaging device according to the sixth embodiment and corresponding to FIG. 12;

FIG. 13B is a cross-sectional diagram illustrating the method of manufacturing the solid-state imaging device according to the sixth embodiment and corresponding to FIG. 12;

FIG. 13C is a cross-sectional diagram illustrating the method of manufacturing the solid-state imaging device according to the sixth embodiment and corresponding to FIG. 12;

FIG. 14 is a cross-sectional diagram illustrating a heat dissipation function of the solid-state imaging device according to the sixth embodiment and corresponding to FIG. 12;

FIG. 15 is a cross-sectional diagram illustrating a camera module to which the solid-state imaging device according to the first embodiment is applied;

FIG. 16A is a cross-sectional diagram illustrating a method of assembling the camera module of FIG. 15 and corresponding to FIG. 15; and

FIG. 16B is a cross-sectional diagram illustrating the method of assembling the camera module of FIG. 15 and corresponding to FIG. 15.

### DESCRIPTION OF THE EMBODIMENTS

Certain embodiments provide a solid-state imaging device including a sensor substrate including a microlens, a transparent resin layer provided so as to be in contact with a main surface of the sensor substrate including a surface of the microlens, and a transparent substrate disposed on a top surface of the transparent resin layer. A thermal conductivity of the transparent resin layer is higher than that of air, and a refractive index of the transparent resin layer is lower than that of the microlens and is equal to or lower than that of the transparent substrate.

Certain embodiments provide a camera module including a solid-state imaging device which receives light, a lens holder which is provided on a top surface of the solid-state imaging device and has a lens which condenses the light to the solid-state imaging device therein, and a shield which is provided to cover a periphery of the lens holder. The solid-state imaging device includes a sensor substrate which includes a pixel including a microlens and receiving the light, a transparent resin layer which is provided so as to be in contact with a main surface of the sensor substrate including a surface of the microlens, a transparent substrate which is disposed on a top surface of the transparent resin layer, and an infrared light blocking film which is provided on a top surface of the transparent substrate. A thermal conductivity of the transparent resin layer is higher than that of air, and a refractive index of the transparent resin layer is lower than that of the microlens and is equal to or lower than that of the transparent substrate.

Certain embodiments provide a method for manufacturing a solid-state imaging device including forming a plurality of light-receiving units, each of which includes a microlens, on a main surface of a semiconductor wafer, forming a transparent resin layer and a transparent substrate in this order on the main surface of the semiconductor wafer including surfaces of the plurality of the microlenses, wherein a thermal conductivity of the transparent resin layer is higher than that of air, and a refractive index of the transparent resin layer is lower than that of the microlens and is equal to or lower than that of the transparent substrate, and cutting the semiconductor wafer, the transparent resin layer, and the transparent substrate corresponding to a space between the plurality of the light-receiving units.

Hereinafter, a solid-state imaging device, a method for manufacturing a solid-state imaging device, and a camera module according to embodiments will be described in detail with reference to the drawings.

### First Embodiment

FIG. 1 is a cross-sectional diagram illustrating a solid-state imaging device according to a first embodiment. The solid-state imaging device 10 illustrated in FIG. 1 is configured to include a sensor substrate 11, a transparent resin layer 12, and a transparent substrate 13.

The sensor substrate 11 receives light and photo-electrically converts the light to generate an electrical signal according to the received light. The sensor substrate 11 is configured by providing a light-receiving unit 15, various signal processing circuits (not shown), and the like in a semiconductor substrate 14.

The semiconductor substrate 14 is, for example, a thin silicon substrate. In addition, the light-receiving unit 15 is formed substantially in a central portion of the semiconductor substrate 14 and is configured by two-dimensionally arranging a plurality of pixels. Each pixel is configured to include at least a photodiode 15a which performs photo-electric conversion and a microlens 15b which condenses light on the photodiode 15a. In addition, although the photodiode 15a is illustrated as one impurity layer in FIG. 1, actually, the photodiodes are separated pixel by pixel. In addition, the signal processing circuits include at least an output circuit which forms an electrical signal based on signal charges formed in the light-receiving unit 15. Besides the output circuit, the various signal processing circuits may include a logic circuit which performs a desired signal process on the electrical signal output from the output circuit.

The transparent resin layer 12 is a resin layer that is transparent to at least a wavelength which the solid-state imaging device 10 is to receive. In this embodiment, the transparent resin layer is a resin layer that is transparent to at least visible light (light in a wavelength range of about 380 nm to about 780 nm). The transparent resin layer 12 is provided so as to be in contact with the main surface of the sensor substrate 11 including a surface of a microlens array which is configured by two-dimensionally arranging a pilot oil of the microlenses 15b.

The transparent resin layer 12 fixes the sensor substrate 11 to the above-described transparent substrate 13 and constitutes a heat dissipation path for dissipating heat generated in the sensor substrate 11 to the transparent substrate 13.

Similarly to the transparent resin layer 12, the transparent substrate 13 is a substrate that is transparent to at least the wavelength which the solid-state imaging device 10 is to receive. In this embodiment, the transparent substrate 13 is a substrate that is transparent to at least visible light (light in a wavelength range of about 380 nm to about 780 nm). The transparent substrate 13 is provided so that the bottom surface of the substrate 13 is in contact with only the top surface of the transparent resin layer 12. Namely, the transparent substrate 13 is supported on the sensor substrate 11 by only the transparent resin layer 12.

The transparent substrate 13 is, for example, a glass substrate and is used as a supporting substrate for thinning the sensor substrate 11.

In the solid-state imaging device 10, the microlenses 15b formed in the sensor substrate 11, the transparent resin layer 12, and the transparent substrate 13 are configured with respective materials having thermal conductivities satisfying the following conditions.

Km>Kair

Kr>Kair

Kg>Kair

Herein, Km is a thermal conductivity of the microlens 15b; Kr is a thermal conductivity of the transparent resin layer 12; Kg is a thermal conductivity of the transparent substrate 13; and Kair is a thermal conductivity of air. In this embodiment, for example, Km is in a range of 0.1 to 0.3 (W/mk), Kr is in a range of 0.1 to 0.3 (W/mk), and Kg is in a range of 1.0 to 1.5 (W/mk).

Furthermore, in the solid-state imaging device 10, the microlenses 15b, the transparent resin layer 12, and the transparent substrate 13 are configured with respective materials having refractive indexes satisfying the following conditions.

Nm>Nr

Nr≦Ng

Herein, Nm is a refractive index of the microlens 15b; Nr is a refractive index of the transparent resin layer 12; and Ng is a refractive index of the transparent substrate 13. In this embodiment, for example, Nm is about 1.8, Nr is about 1.2, and Ng is about 1.5.

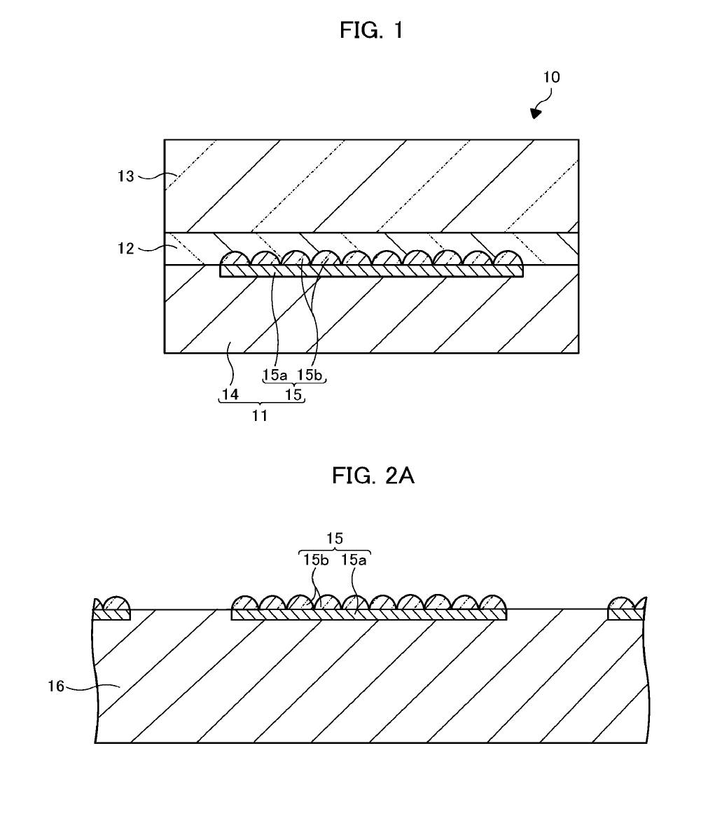

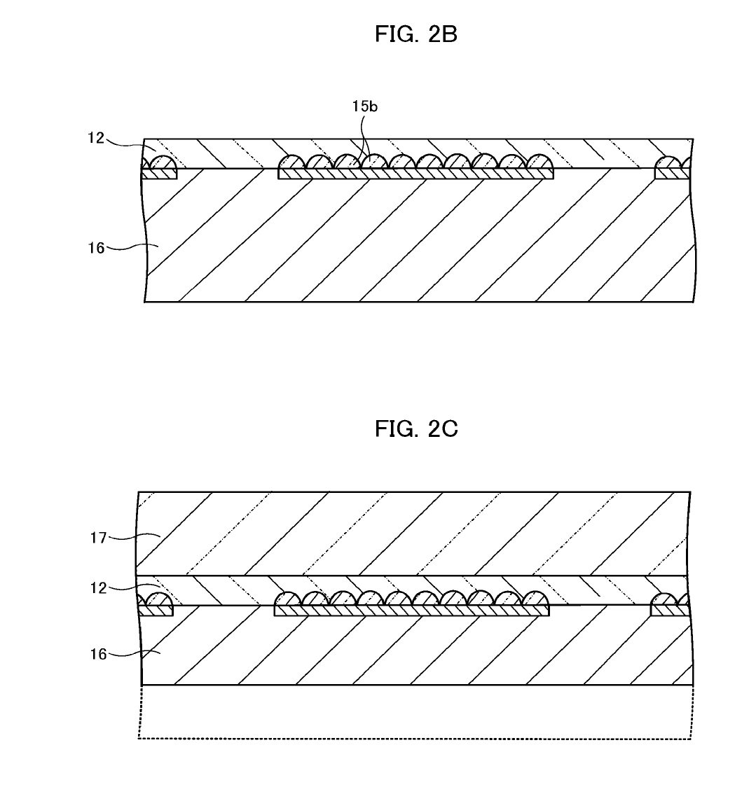

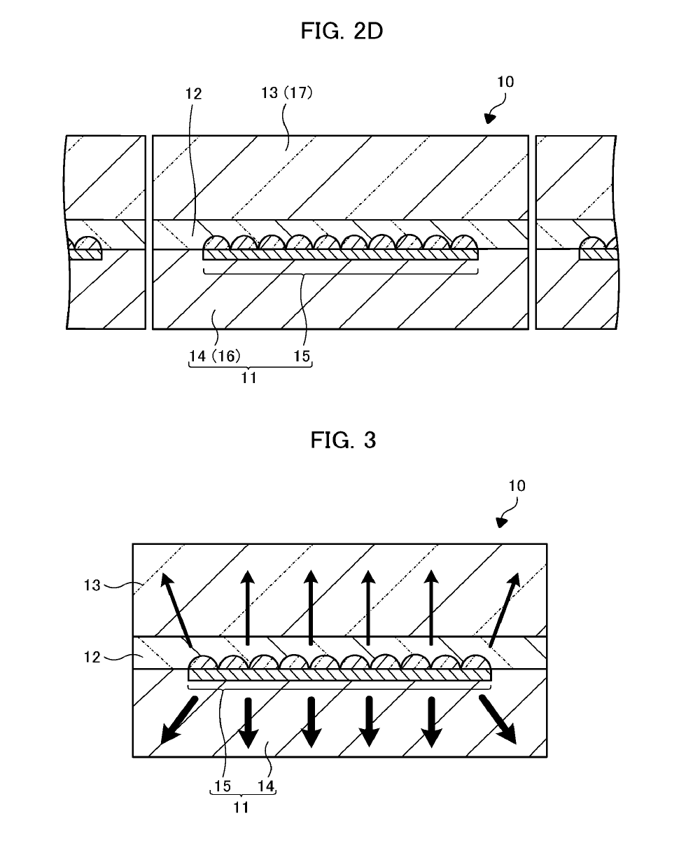

FIGS. 2A to 2D are cross-sectional diagrams illustrating a method of manufacturing the solid-state imaging device 10 according to the embodiment and corresponding to FIG. 1. Hereinafter, the method of manufacturing the solid-state imaging device 10 according to the embodiment will be described with reference to FIGS. 2A to 2D. In addition, all the processes performed in the manufacturing method are performed in a wafer state.

First, as illustrated in FIG. 2A, the light-receiving unit 15 is formed by two-dimensionally arranging pixels, each of which includes a photodiode 15a and microlenses 15b, on the main surface of the silicon wafer 16 as an example of a semiconductor wafer. For example, the photodiode 15a is formed by injecting a desired conductivity type of ions into the surface of the silicon wafer 16, and the microlenses 15b are formed by shaping a patterned block-shaped microlens material in a lens shape by a melting method. In addition, in this process, various signal processing circuits may be formed.

Next, as illustrated in FIG. 2B, the transparent resin layer 12 is formed so as to be in contact with the entire main surface of the silicon wafer 16 including the surface of the microlens array configured with a plurality of the microlenses 15b. The transparent resin layer 12 is formed, for example, by applying a transparent resin material on the main surface of the silicon wafer 16 by a spin coating method.

Next, as illustrated in FIG. 2C, a glass wafer 17 as an example of a transparent substrate is disposed to be in contact with the top surface of the transparent resin layer 12, and the glass wafer 17 and the silicon wafer 16 are fixed to each other through the transparent resin layer 12. This is performed, for example, by curing the transparent resin layer 12 by using means such as heating and UV light illuminating.

By doing so, after the silicon wafer 16 is supported on the glass wafer 17, the silicon wafer 16 is thinned. The thinning of the silicon wafer 16 is performed, for example, by polishing the rear surface of the silicon wafer 16 until the wafer 16 has a predetermined thickness.

Finally, as illustrated in FIG. 2D, a plurality of the solid-state imaging devices 10 which are formed in a wafer state are individualized. By the individualization, the silicon wafer 16 including the light-receiving unit 15 and the like becomes the sensor substrate 11, and the glass wafer 17 becomes the transparent substrate 13. In addition, the individualization is performed, for example, as follows. First, a plurality of the solid-state imaging devices 10 which are formed in a wafer state are fixed to a supporting member such as a dicing tape. Next, the silicon wafer 16, the transparent resin layer 12, and the glass substrate 17 corresponding to a space between the light-receiving units 15 are cut by dicing. Finally, each cut solid-state imaging device 10 is peeled off from the supporting member. By doing so, a plurality of the solid-state imaging devices 10 are individualized.

By doing so, as illustrated in FIG. 1, a chip-scale type of the solid-state imaging device 10 where the sensor substrate 11, the transparent resin layer 12, and the transparent substrate 13 are substantially equal to each other in terms of size can be manufactured. In addition, “substantially equal to each other in terms of size” denotes that, as the solid-state imaging device 10 is seen from the top side (as the solid-state imaging device 10 is seen from the top side of the transparent substrate 13), the sensor substrate 11, the transparent resin layer 12, and the transparent substrate 13 are substantially the same in terms of shape and area. In the embodiments described hereinafter, similarly, “substantially equal to each other in terms of size” has the same as the above-described meaning.

FIG. 3 is a cross-sectional diagram illustrating a heat dissipation function of the solid-state imaging device 10 having the above-described configuration and corresponding to FIG. 1. In the solid-state imaging device 10 according to the embodiment, in the case where the sensor substrate 11 dissipates heat, as indicated by the arrows in the figure, he heat is dissipated through the semiconductor substrate 14 downwards from the solid-state imaging device 10. Furthermore, as indicated by the arrows in the same figure, the heat generated from the sensor substrate 11 is also dissipated to the transparent resin layer 12 which is in contact with the main surface of the sensor substrate 11. The heat dissipated to the transparent resin layer 12 is also dissipated through the transparent substrate 13 upwards from the solid-state imaging device 10. By doing so, in the solid-state imaging device 10 according to the embodiment, the heat dissipation path of the heat generated from the sensor substrate 11 can be increased. Therefore, the solid-state imaging device 10 according to the embodiment has a good heat dissipation property.

In contrast, like the solid-state imaging device in the related art, in the case where a space is provided between the light-receiving unit and the transparent substrate, since the space is filled with air having a low thermal conductivity, the heat dissipation through the space does not nearly occur. Therefore, the solid-state imaging device in the related art has a poor heat dissipation property.

According to the solid-state imaging device 10 according to the first embodiment and the manufacturing method therefor described heretofore, the transparent resin layer 12 having a thermal conductivity higher than that of air is formed between the main surface of the sensor substrate 11 and the transparent substrate 13 so as to fill the space therebetween. Therefore, it is possible to provide a solid-state imaging device having a good heat dissipation path and a manufacturing method therefor.

Furthermore, according to the solid-state imaging device 10 according to the first embodiment and the manufacturing method therefor, the transparent resin layer 12 having a refractive index lower than that of the microlens 15b and equal to or lower than that of the transparent substrate 13 is formed between the main surface of the sensor substrate 11 and the transparent substrate 13 so as to fill the space therebetween. Therefore, a reflection amount on the interface to the microlenses 15b and a reflection amount on the interface to the transparent substrate 13 are suppressed. Therefore, it is possible to provide a solid-state imaging device having a good sensitivity and a manufacturing method therefor.

In this manner, the heat dissipation property and the sensitivity are improved, so that it is possible to provide a solid-state imaging device having improved imaging characteristics and a manufacturing method therefor.

In addition, according to the solid-state imaging device 10 according to the first embodiment and the manufacturing method therefor, since the transparent resin layer 12 is buried between the main surface of the very thin sensor substrate 11 and the transparent substrate 13, warping of the sensor substrate 11 can be suppressed.

Furthermore, according to the solid-state imaging device 10 according to the first embodiment and the manufacturing method therefor, the solid-state imaging device can be easily manufactured. Hereinafter, this will be described more in detail.

In the solid-state imaging device in the related art, in order to improve the heat dissipation property, the case where a space surrounded by adhesive between a light-receiving unit and a glass substrate is filled with a transparent resin is considered. The solid-state imaging device can be manufactured by fixing a transparent substrate on a sensor substrate through adhesive, forming a hole in the transparent substrate, and filling the transparent resin into the space through the hole.

In contrast, according to the solid-state imaging device 10 according to the first embodiment and the manufacturing method therefor, since the transparent resin layer 12 is formed on the entire main surface of the sensor substrate 11 and the transparent substrate 13 is fixed on the top surface of the transparent resin layer 12, processes of fixing the transparent substrate and filling with the transparent resin need not to be individually provided. Furthermore, any hole in the transparent substrate for filling with the transparent resin needs not to be provided. Therefore, the solid-state imaging device 10 according to the first embodiment can be easily manufactured.

### Second Embodiment

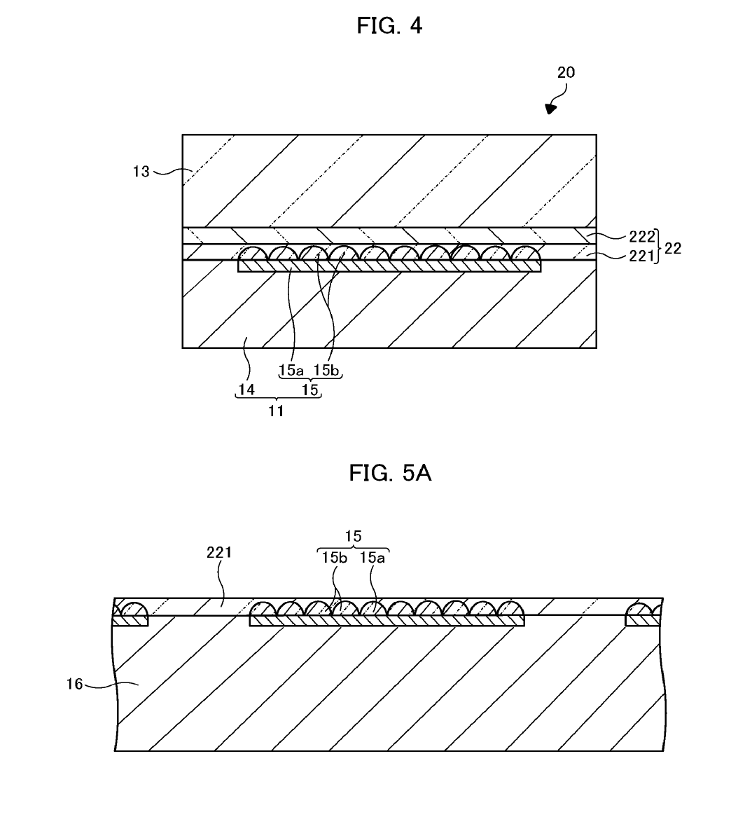

FIG. 4 is a cross-sectional diagram illustrating a solid-state imaging device according to a second embodiment. The solid-state imaging device 20 illustrated in FIG. 4 is different from the solid-state imaging device 10 according to the first embodiment in terms of structure of a transparent resin layer 22. Therefore, hereinafter, the transparent resin layer 22 of the solid-state imaging device 20 according to the second embodiment will be described. In addition, a sensor substrate 11 and a transparent substrate 13 of the solid-state imaging device 20 are the same as the sensor substrate 11 and the transparent substrate 13 of the solid-state imaging device 10 according to the first embodiment. Therefore, the sensor substrate 11 and the transparent substrate 13 of the solid-state imaging device 20 are denoted by the same reference numerals of the sensor substrate 11 and the transparent substrate 13 of the solid-state imaging device 10 according to the first embodiment, and the description of the sensor substrate 11 and the transparent substrate 13 of the solid-state imaging device 20 is omitted.

The transparent resin layer 22 of the solid-state imaging device 20 according to the second embodiment is configured to include a first resin layer 221 which is provided so as to be in contact with the main surface of the sensor substrate 11 including a surface of a microlens array configured with a plurality of microlenses 15b and a second resin layer 222 which is provided on the entire top surface of the first resin layer 221.

The first resin layer 221 is the same resin layer as the transparent resin layer 12 of the solid-state imaging device 10 according to the first embodiment. The first resin layer 221 is a resin layer that is transparent to at least a wavelength which the solid-state imaging device 20 is to receive (for example, visible light (light in a wavelength range of about 380 nm to about 780 nm)). The first resin layer 221 constitutes a heat dissipation path for dissipating heat generated in the sensor substrate 11 upwards (to the transparent substrate 13 side). The top surface of the first resin layer 221 has a substantially planar shape.

Similarly to the first resin layer 221, the second resin layer 222 is a resin layer that is transparent to at least a wavelength which the solid-state imaging device 20 is to receive (for example, visible light (light in a wavelength range of about 380 nm to about 780 nm)) and constitutes a heat dissipation path. Furthermore, the second resin layer 222 fixes the sensor substrate 11 including the first resin layer 221 to the transparent substrate 13.

The transparent substrate 13 is provided so that the bottom surface of the substrate 13 is in contact with only the top surface of the transparent resin layer 22 (top surface of the second resin layer 222) having the lamination structure described above.

In the solid-state imaging device 20, the microlenses 15b formed in the sensor substrate 11, the first resin layer 221, the second resin layer 222, and the transparent substrate 13 are configured with respective materials having thermal conductivities satisfying the following conditions.

Km>Kair

Kr1>Kair

Kr2>Kair

Kg>Kair

Herein, Kr1 is a thermal conductivity of the first resin layer 221; and Kr2 is a thermal conductivity of the second resin layer 222. In this embodiment, for example, Kr1 is in a range of 0.1 to 0.3 (W/mk), and Kr2 is in a range of 0.1 to 0.3 (W/mk).

Furthermore, in the solid-state imaging device 20, microlenses 15b, the first resin layer 221, the second resin layer 222, and the transparent substrate 13 are configured with respective materials having refractive indexes satisfying the following conditions.

Nm>Nr1

Nm>Nr2

Nr1≦Ng

Herein, Nr1 is a refractive index of the first resin layer 221; and Nr2 is a refractive index of the second resin layer 222. In this embodiment, for example, Nr1 is about 1.2, and Nr2 is about 1.5.

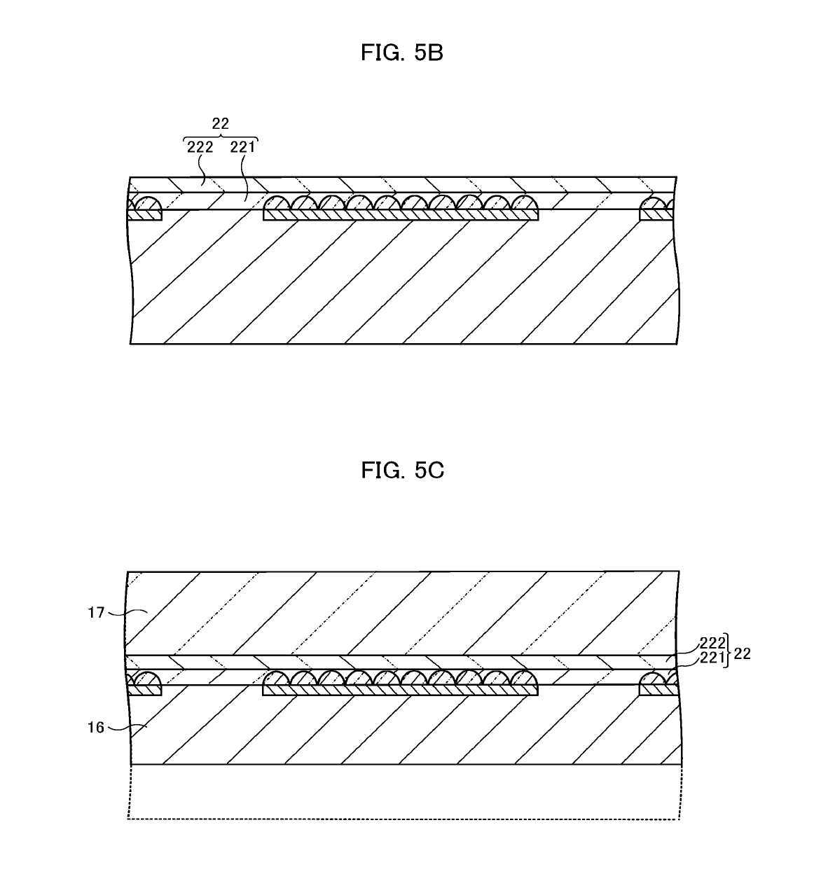

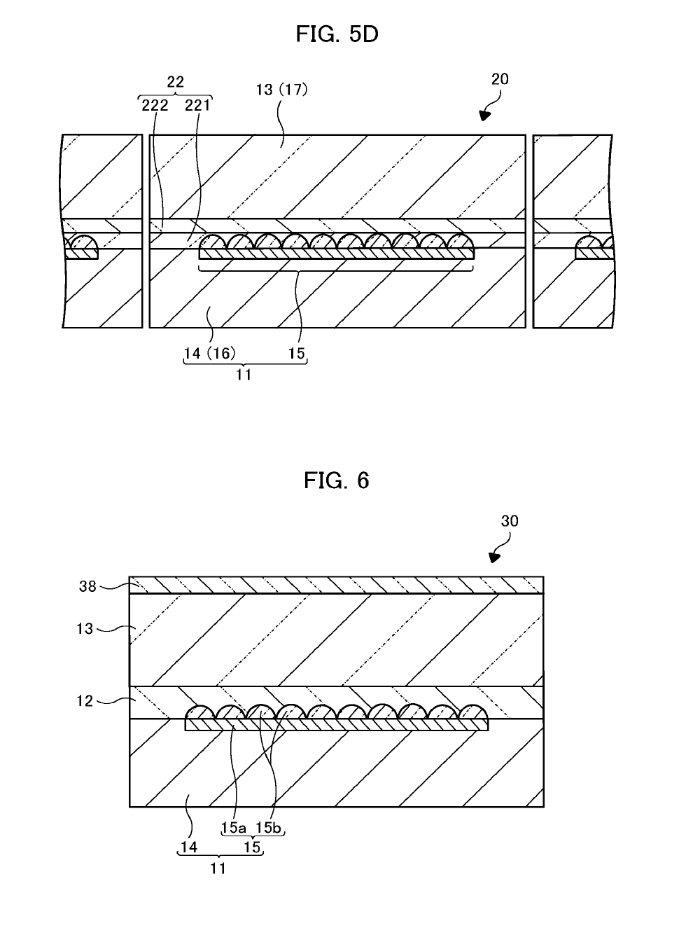

FIGS. 5A to 5D are cross-sectional diagrams illustrating a method of manufacturing the solid-state imaging device 20 according to the embodiment and corresponding to FIG. 4. Hereinafter, the method of manufacturing the solid-state imaging device 20 according to the embodiment will be described with reference to FIGS. 5A to 5D. In addition, all the processes performed in the manufacturing method are performed in a wafer state.

First, as illustrated in FIG. 5A, the light-receiving unit 15 is formed by two-dimensionally arranging pixels, each of which includes a photodiode 15a and microlenses 15b, on the main surface of a silicon wafer 16 as an example of a semiconductor wafer. In this process, various signal processing circuits may be formed. Next, the first resin layer 221 is formed so as to be in contact with the entire main surface of the silicon wafer 16 including the surface of the microlens array configured with a plurality of the microlenses 15b. The first resin layer 221 can be formed, for example, by applying a resin material constituting the first resin layer 221 on the main surface of the silicon wafer 16 by a spin coating method. The top surface of the first resin layer 221 formed as described above has a substantially planar shape.

Next, as illustrated in FIG. 5B, the second resin layer 222 is formed on the entire top surface of the first resin layer 221. Similarly to the first resin layer 221, the second resin layer 222 can also be formed by applying a resin material constituting the second resin layer 222 on the entire top surface of the first resin layer 221 by a spin coating method. By doing so, the transparent resin layer 22 is formed to be configured to include the first resin layer 221 and the second resin layer 222.

Next, as illustrated in FIG. 5C, a glass wafer 17 as an example of a transparent substrate is disposed on the top surface of the transparent resin layer 22, and the glass wafer 17 and the silicon wafer 16 are fixed to each other through the transparent resin layer 22. By doing so, after the silicon wafer 16 is supported on the glass wafer 17, the silicon wafer 16 is thinned.

Finally, as illustrated in FIG. 5D, a plurality of the solid-state imaging devices 20 which are formed in a wafer state are individualized. By the individualization, the silicon wafer 16 including the light-receiving unit 15 and the like becomes the sensor substrate 11, and the glass wafer 17 becomes the transparent substrate 13.

By doing so, as illustrated in FIG. 4, a chip-scale type of the solid-state imaging device 20 where the sensor substrate 11, the transparent resin layer 22, and the transparent substrate 13 are substantially equal to each other in terms of size can be manufactured.

In addition, the heat dissipation function in the solid-state imaging device 20 is the same as described with reference to FIG. 3, and thus, the description thereof is omitted.

In the solid-state imaging device 20 according to the second embodiment and the manufacturing method therefor described heretofore, for the same reason as that of the solid-state imaging device 10 according to the first embodiment and the manufacturing method therefor, the heat dissipation property and the sensitivity are improved. Therefore, it is possible to provide a solid-state imaging device having an improved imaging characteristics and a manufacturing method therefor. In addition, similarly to the solid-state imaging device 10 according to the first embodiment and the manufacturing method therefor, the warping of the sensor substrate 11 can be suppressed, and the solid-state imaging device 20 according to the second embodiment can be easily manufactured.

In addition, in the solid-state imaging device 20 according to the second embodiment described above, the first resin layer 221 and the second resin layer 222 are configured to satisfy the following relationship.

Kair<Kr1

Kair<Kr2

Nr1≦Ng

Nr1≦Nr2<Nm

The first resin layer 221 and the second resin layer 222 are configured in this manner, so that a rapid change in thermal conductivity and refractive index between the sensor substrate 11 including the microlenses 15b and the transparent substrate 13 can be suppressed. Therefore, better heat dissipation property can be obtained, and reflection of incident light can be further suppressed.

### Third Embodiment

FIG. 6 is a cross-sectional diagram illustrating a solid-state imaging device according to a third embodiment. The solid-state imaging device 30 illustrated in FIG. 6 is different from the solid-state imaging device 10 according to the first embodiment in terms that the top surface of a transparent substrate 13 is subject to infrared light (IR) cut coating. Namely, in the solid-state imaging device 30 according to the third embodiment, an infrared light blocking film 38 is provided on the top surface of the transparent substrate 13. In addition, a sensor substrate 11, a transparent resin layer 12, and the transparent substrate 13 of the solid-state imaging device 30 are the same as the sensor substrate 11, the transparent resin layer 12, and the transparent substrate 13 of the solid-state imaging device 10 according to the first embodiment. Therefore, the sensor substrate 11, the transparent resin layer 12, and the transparent substrate 13 of the solid-state imaging device 30 are denoted by the same reference numerals of the sensor substrate 11, the transparent resin layer 12, and the transparent substrate 13 of the solid-state imaging device 10 according to the first embodiment, and in the following description, the description of the sensor substrate 11, the transparent resin layer 12, and the transparent substrate 13 of the solid-state imaging device 30 is omitted.

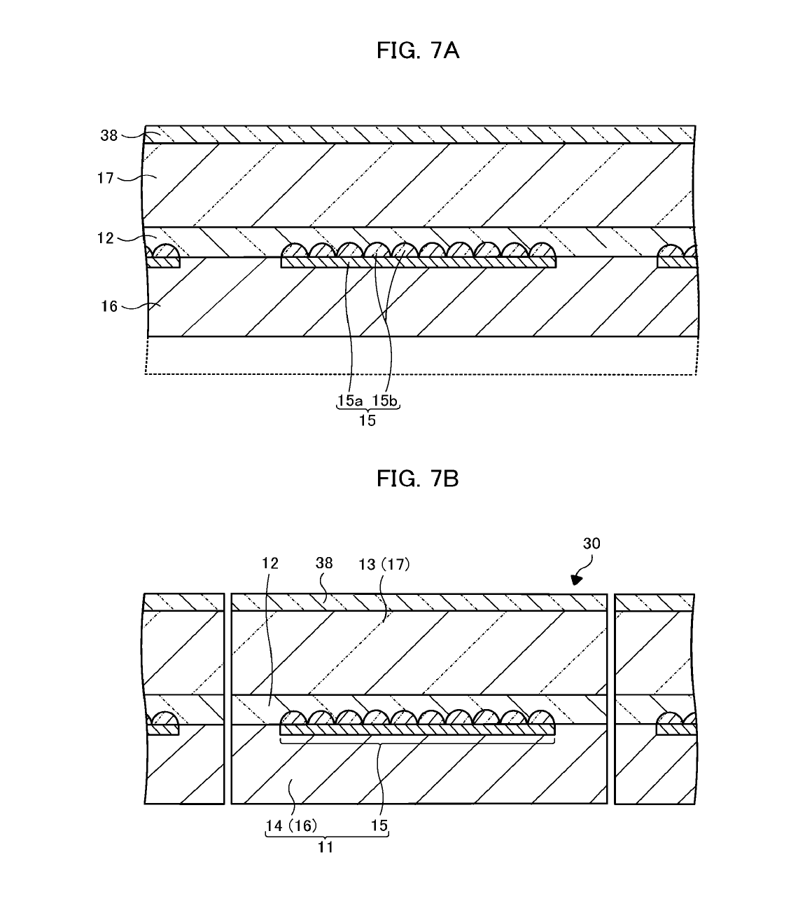

FIGS. 7A and 7B are cross-sectional diagrams illustrating a method for manufacturing the solid-state imaging device according to the embodiment and corresponding to FIG. 6. Herein, the method of manufacturing the solid-state imaging device 30 according to the embodiment will be described with reference to FIGS. 7A and 7B. In addition, all the processes performed in the manufacturing method are performed in a wafer state.

First, through the processes illustrated in FIGS. 2A and 2B, a light-receiving unit 15 is formed by two-dimensionally arranging pixels, each of which includes a photodiode 15a and microlenses 15b, on the main surface of a silicon wafer 16 as an example of a semiconductor wafer. Subsequently, the transparent resin layer 12 is formed so as to be in contact with the entire main surface of the silicon wafer 16 including the surface of the microlens array configured with a plurality of the microlenses 15b.

After that, as illustrated in FIG. 7A, a glass wafer 17, on the top surface of which the infrared light blocking film 38 is provided, is disposed so that the bottom surface thereof is in contact with the top surface of the transparent resin layer 12, and the silicon wafer 16 is fixed to the glass wafer 17 through the transparent resin layer 12. By doing so, after the silicon wafer 16 is supported on the glass wafer 17, the silicon wafer 16 is thinned.

Finally, as illustrated in FIG. 7B, a plurality of the solid-state imaging devices 30 which are formed in a wafer state are individualized. By the individualization, the silicon wafer 16 including the light-receiving unit 15 and the like becomes the sensor substrate 11, and the glass wafer 17 becomes the transparent substrate 13.

By doing so, as illustrated in FIG. 6, a chip-scale type of the solid-state imaging device 30 where the sensor substrate 11, the transparent resin layer 12, and the transparent substrate 13 are substantially equal to each other in terms of size can be manufactured.

In addition, the heat dissipation function in the solid-state imaging device 30 is the same as described with reference to FIG. 3, and thus, the description thereof is omitted.

In the solid-state imaging device 30 according to the third embodiment and the manufacturing method therefor described heretofore, for the same reason as that of the solid-state imaging device 10 according to the first embodiment and the manufacturing method therefor, the heat dissipation property and the sensitivity are improved. Therefore, it is possible to provide a solid-state imaging device having improved imaging characteristics and a manufacturing method therefor. In addition, similarly to the solid-state imaging device 10 according to the first embodiment and the manufacturing method therefor, the warping of the sensor substrate 11 can be suppressed, and the solid-state imaging device 30 according to the third embodiment can be easily manufactured.

Furthermore, in the solid-state imaging device 30 according to the third embodiment, an infrared light blocking film 38 is provided on the top surface of the transparent substrate 13. Therefore, a deterioration of the imaged image caused by noise associated with reception of infrared light in the light-receiving unit 15 can be suppressed.

### Fourth Embodiment

FIG. 8 is a cross-sectional diagram illustrating a solid-state imaging device according to a fourth embodiment. The solid-state imaging device 40 illustrated in FIG. 8 is different from the solid-state imaging device 10 according to the first embodiment in terms that a transparent substrate 43 is an infrared light blocking glass which transmits visible light and blocks infrared light. In addition, the sensor substrate 11 and the transparent resin layer 12 of the solid-state imaging device 40 are the same as the sensor substrate 11 and the transparent resin layer 12 of the solid-state imaging device 10 according to the first embodiment. Therefore, the sensor substrate 11 and the transparent resin layer 12 of the solid-state imaging device 40 are denoted by the same reference numerals of the sensor substrate 11 and the transparent resin layer 12 of the solid-state imaging device 10 according to the first embodiment, and in the following description, the description of the sensor substrate 11 and the transparent resin layer 12 of the solid-state imaging device 40 is omitted.

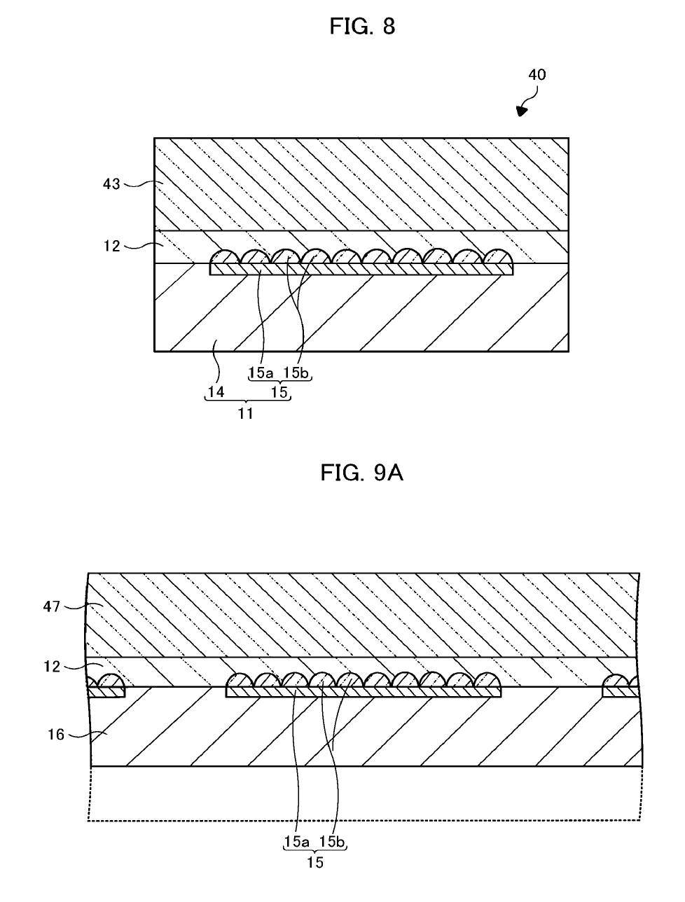

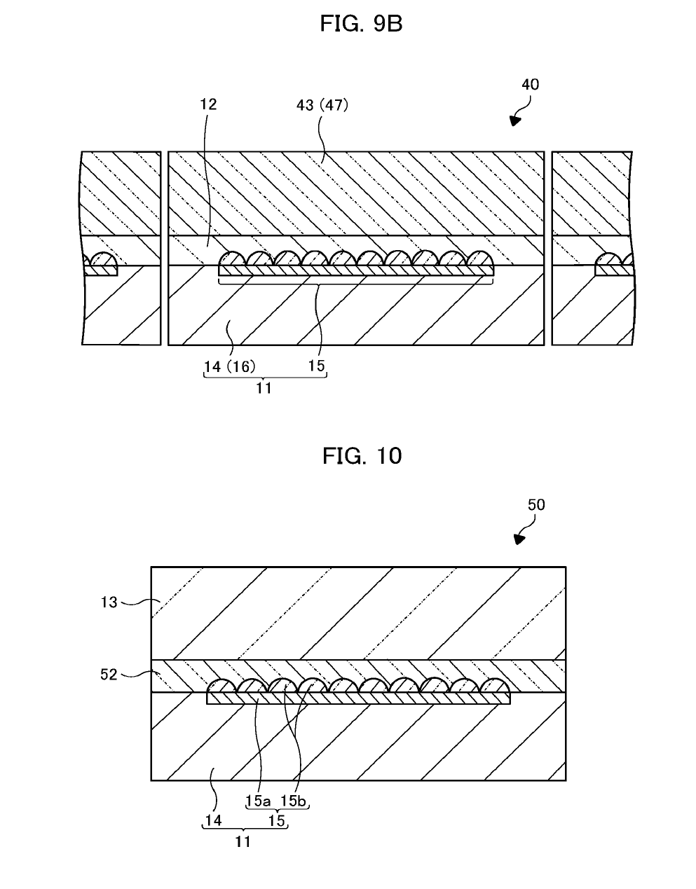

FIGS. 9A and 9B are cross-sectional diagrams illustrating a method of manufacturing the solid-state imaging device 40 according to the embodiment and corresponding to FIG. 8. Hereinafter, the method of manufacturing the solid-state imaging device 40 according to the embodiment will be described with reference to FIGS. 9A and 9B. In addition, all the processes performed in the manufacturing method are performed in a wafer state.

First, through the processes illustrated in FIGS. 2A and 2B, a light-receiving unit 15 is formed by two-dimensionally arranging pixels, each of which includes a photodiode 15a and microlenses 15b, on the main surface of the silicon wafer 16 as an example of a semiconductor wafer. Subsequently, the transparent resin layer 12 is formed so as to be in contact with the entire main surface of a silicon wafer 16 including the surface of the microlens array configured with a plurality of the microlenses 15b.

After that, as illustrated in FIG. 9A, a glass wafer 47 having an infrared light blocking function is disposed so that the bottom surface thereof is in contact with the top surface of the transparent resin layer 12, and the silicon wafer 16 is fixed to the glass wafer 47 through the transparent resin layer 12. By doing so, after the silicon wafer 16 is supported on the glass wafer 47, the silicon wafer 16 is thinned.

Finally, as illustrated in FIG. 9B, a plurality of the solid-state imaging devices 40 which are formed in a wafer state are individualized. By the individualization, the silicon wafer 16 including the light-receiving unit 15 and the like becomes the sensor substrate 11, and the glass wafer 47 becomes the transparent substrate 43 configured with an infrared light blocking glass.

By doing so, as illustrated in FIG. 8, a chip-scale type of the solid-state imaging device 40 where the sensor substrate 11, the transparent resin layer 12, and the transparent substrate 43 are substantially equal to each other in terms of size can be manufactured.

The heat dissipation function in the solid-state imaging device 40 is the same as described with reference to FIG. 3, and thus, the description thereof is omitted.

In the solid-state imaging device 40 according to the fourth embodiment and the manufacturing method therefor described heretofore, for the same reason as that of the solid-state imaging device 10 according to the first embodiment and the manufacturing method therefor, the heat dissipation property and the sensitivity are improved. Therefore, it is possible to provide a solid-state imaging device having improved imaging characteristics and a manufacturing method therefor. In addition, similarly to the solid-state imaging device 10 according to the first embodiment and the manufacturing method therefor, the warping of the sensor substrate 11 can be suppressed, and the solid-state imaging device 40 according to the fourth embodiment can be easily manufactured.

Furthermore, in the solid-state imaging device 40 according to the fourth embodiment, since the transparent substrate 43 is configured with an infrared light blocking glass having an infrared light blocking function, a deterioration of the imaged image caused by noise associated with reception of infrared light in the light-receiving unit can be suppressed.

### Fifth Embodiment

FIG. 10 is a cross-sectional diagram illustrating a solid-state imaging device according to a fifth embodiment. The solid-state imaging device 50 illustrated in FIG. 10 is different from the solid-state imaging device 10 according to the first embodiment in terms that a transparent resin layer 52 has a function of transmitting visible light and blocking infrared light. As a resin material constituting the transparent resin layer 52, a resin material having, for example, a thermal conductivity Kr of 0.1 to 0.3 (W/mk), and a refractive index Nr of 1.2 can be applied. In addition, a sensor substrate 11 and a transparent substrate 13 of the solid-state imaging device 50 are the same as the sensor substrate 11 and the transparent substrate 13 of the solid-state imaging device 10 according to the first embodiment. Therefore, the sensor substrate 11 and the transparent substrate 13 of the solid-state imaging device 50 are denoted by the same reference numerals of the sensor substrate 11 and the transparent substrate 13 of the solid-state imaging device 10 according to the first embodiment, and in the following description, the description of the sensor substrate 11 and the transparent substrate 13 of the solid-state imaging device 50 is omitted.

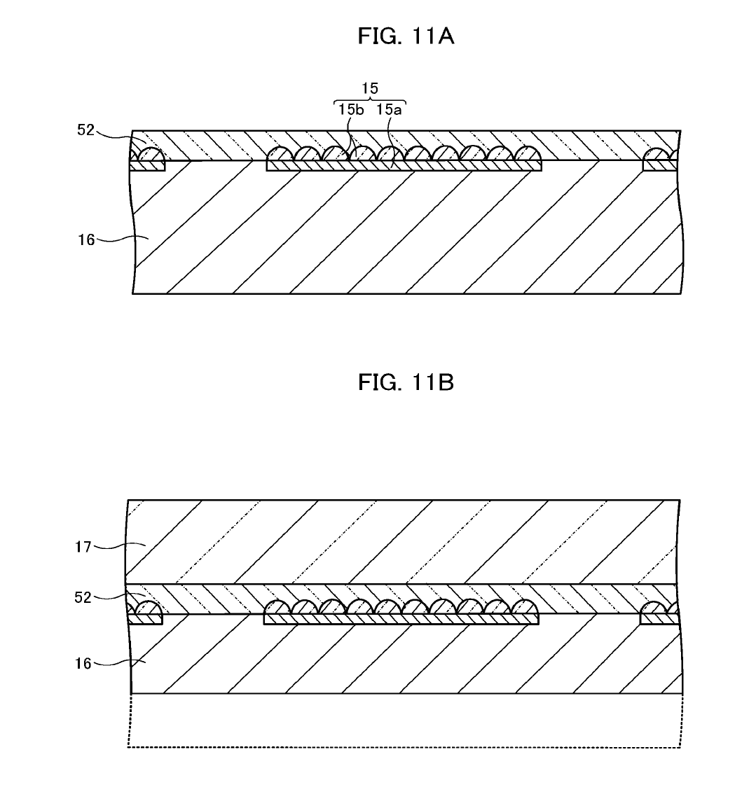

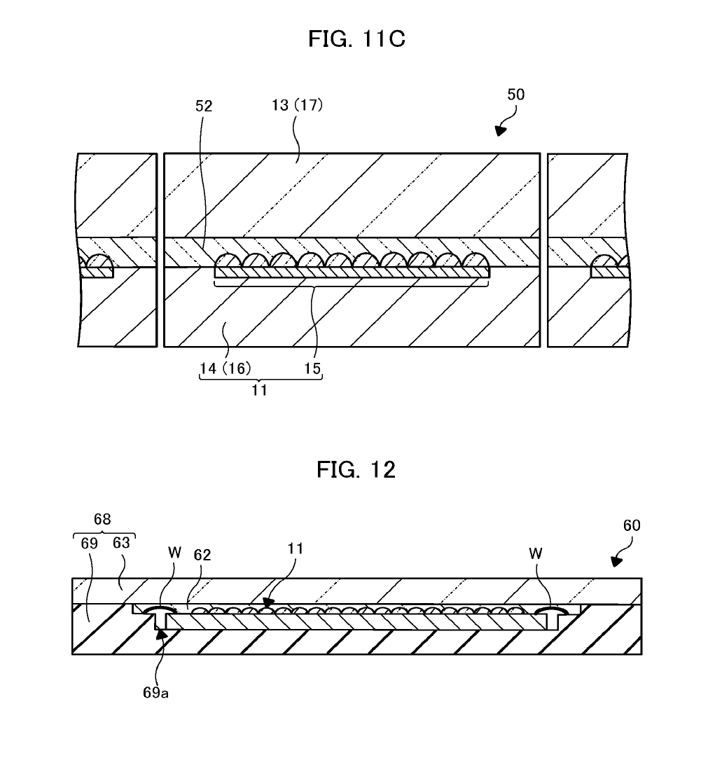

FIGS. 11A to 11C are cross-sectional diagrams illustrating a method of manufacturing the solid-state imaging device 50 according to the embodiment and corresponding to FIG. 10. Hereinafter, the method of manufacturing the solid-state imaging device 50 according to the embodiment will be described with reference with FIGS. 11A to 11C. In addition, all the processes performed in the manufacturing method are performed in a wafer state.

First, through the processes illustrated in FIG. 2A, a light-receiving unit 15 is formed by two-dimensionally arranging pixels, each of which includes a photodiode 15a and microlenses 15b, on the main surface of a silicon wafer 16 as an example of a semiconductor wafer.

Next, as illustrated in FIG. 11A, the transparent resin layer 52 configured with a resin material transmitting visible light and blocking infrared light is formed so as to be in contact with the entire main surface of the silicon wafer 16 including the surface of the microlens array configured with a plurality of the microlenses 15b. The transparent resin layer 52 can also be formed, for example, by applying a resin material which transmits visible light and block infrared light on the main surface of the silicon wafer 16 by a spin coating method.

Next, as illustrated in FIG. 11B, a glass wafer 17 as an example of a transparent substrate to be contact with the top surface of the transparent resin layer 52, and the silicon wafer 16 and the glass wafer 17 are fixed to each other through the transparent resin layer 52. This is also performed, for example, by curing the transparent resin layer 52 by using means such as heating and UV light illuminating.

By doing so, after the silicon wafer 16 is supported on the glass wafer 17, the silicon wafer 16 is thinned.

Finally, as illustrated in FIG. 11C, a plurality of the solid-state imaging devices 50 which are formed in a wafer state are individualized. By the individualization, the silicon wafer 16 including the light-receiving unit 15 and the like becomes the sensor substrate 11, and the glass wafer 17 becomes the transparent substrate 13.

By doing so, as illustrated in FIG. 10, a chip-scale type of the solid-state imaging device 50 where the sensor substrate 11, the transparent resin layer 52, and the transparent substrate 13 are substantially equal to each other in terms of size can be manufactured.

The heat dissipation function in the solid-state imaging device 50 is the same as described with reference to FIG. 3, and thus, the description thereof is omitted.

In the solid-state imaging device 50 according to the fifth embodiment and the manufacturing method therefor described heretofore, for the same reason as that of the solid-state imaging device 10 according to the first embodiment and the manufacturing method therefor, the heat dissipation property and the sensitivity are improved. Therefore, it is possible to provide a solid-state imaging device having improved imaging characteristics and a manufacturing method therefor. In addition, similarly to the solid-state imaging device 10 according to the first embodiment and the manufacturing method therefor, the warping of the sensor substrate 11 can be suppressed, and the solid-state imaging device 50 according to the fifth embodiment can be easily manufactured.

Furthermore, in the solid-state imaging device 50 according to the fifth embodiment, since the transparent resin layer 52 is configured with a resin material having an infrared light blocking function, a deterioration of the imaged image caused by noise associated with reception of infrared light in the light-receiving unit 15 can be suppressed.

### Sixth Embodiment

FIG. 12 is a cross-sectional diagram illustrating a solid-state imaging device according to a sixth embodiment. The solid-state imaging device 60 illustrated in FIG. 12 is a sensor package mounted on a digital camera or the like and is configured with a sensor substrate 11 and a package 68 and accommodating the sensor substrate 11. In addition, the sensor substrate 11 is the same as the sensor substrate 11 described in each of the first to fifth embodiments. Therefore, the sensor substrate 11 of the solid-state imaging device 60 according to the embodiment is denoted by the same reference numeral as that of the sensor substrate 11 described in each of the first to fifth embodiments, and the description of the sensor substrate 11 of the solid-state imaging device 60 according to the embodiment is omitted.

The package 68 is configured to include a housing 69 having a concave accommodating portion 69a on the top surface of a dielectric block and a transparent substrate 63 provided on the top surface of the housing 69 to cover the accommodating portion 69a. The dielectric block is configured, for example, with a ceramic. In addition, the transparent substrate 63 is configured, for example, with a glass substrate.

The sensor substrate 11 is disposed inside a space provided between the accommodating portion 69a of the housing 69 and the transparent substrate 63 and is electrically connected to wire lines (not shown) provided in the housing 69 through wires W. By doing so, the sensor substrate 11 is provided inside the space of the package 68.

In addition, a transparent resin layer 62 is formed inside the space of the package 68 where the sensor substrate 11 is provided. The transparent resin layer 62 is formed to fill the space of the package 68.

Herein, in the solid-state imaging device 60 according to the embodiment, the transparent substrate 63 of the package 68 is the same as the transparent substrate 13 of the solid-state imaging device 10 according to the first embodiment, and the transparent resin layer 62 is the same as the transparent resin layer 12 of the solid-state imaging device 10 according to the first embodiment. However, the transparent substrate 63 of the solid-state imaging device 60 according to the embodiment, may be the same as the transparent substrates 13 and 43 of the solid-state imaging devices 20, 30, 40, and 50 according to the second to fifth embodiments, and the transparent resin layer 62 may be the same as the transparent resin layers 12, 22, and 52 of the solid-state imaging devices 20, 30, 40, and 50 according to the second to fifth embodiments.

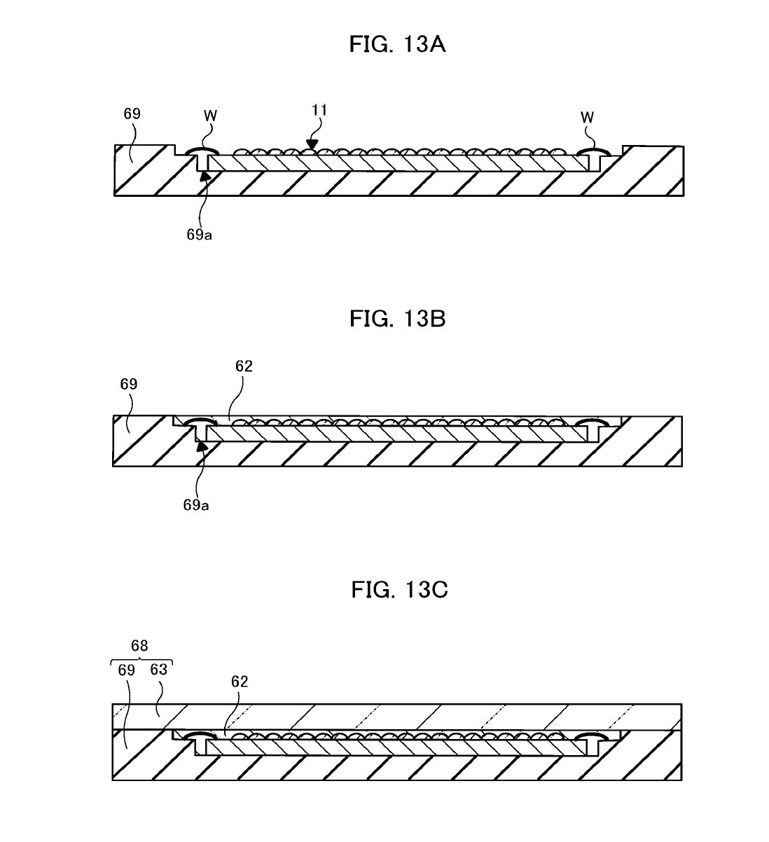

FIGS. 13A to 13C are cross-sectional diagrams illustrating a method of manufacturing the solid-state imaging device 60 according to the embodiment and corresponding to FIG. 12. Hereinafter, the method of manufacturing the solid-state imaging device 60 according to the embodiment will be described with reference with FIGS. 13A to 13C. In addition, this manufacturing method is not a method of collectively manufacturing solid-state imaging devices in a wafer state but a method of individually manufacturing the solid-state imaging devices 60.

First, as illustrated in FIG. 13A, the sensor substrate 11 is disposed inside the accommodating portion 69a of the housing 69, and the wire lines are electrically connected to each other by using wires W. By doing so, the sensor substrate 11 is mounted on the housing 69.

Next, as illustrated in FIG. 13B, the transparent resin layer 62 is formed so as to fill the accommodating portion 69a of the housing 69. After that, as illustrated in FIG. 13C, the transparent substrate 63 is provided on the top surface of the housing 69 including the top surface of the transparent resin layer 62.

In addition, after the transparent substrate 63 is provided on the top surface of the housing 69, the transparent resin layer 62 may be formed so as to fill the space between the housing 69 and the transparent substrate 63. However, in this case, an injection hole for injecting the transparent resin layer 62 into the space is required. Therefore, as illustrated in FIGS. 13B and 13C, a method of forming the transparent resin layer 62 and, after that, providing the transparent substrate 63 on the top surface of the housing 69 is more preferred.

By doing so, it is possible to manufacture the solid-state imaging device 60 illustrated in FIG. 12.

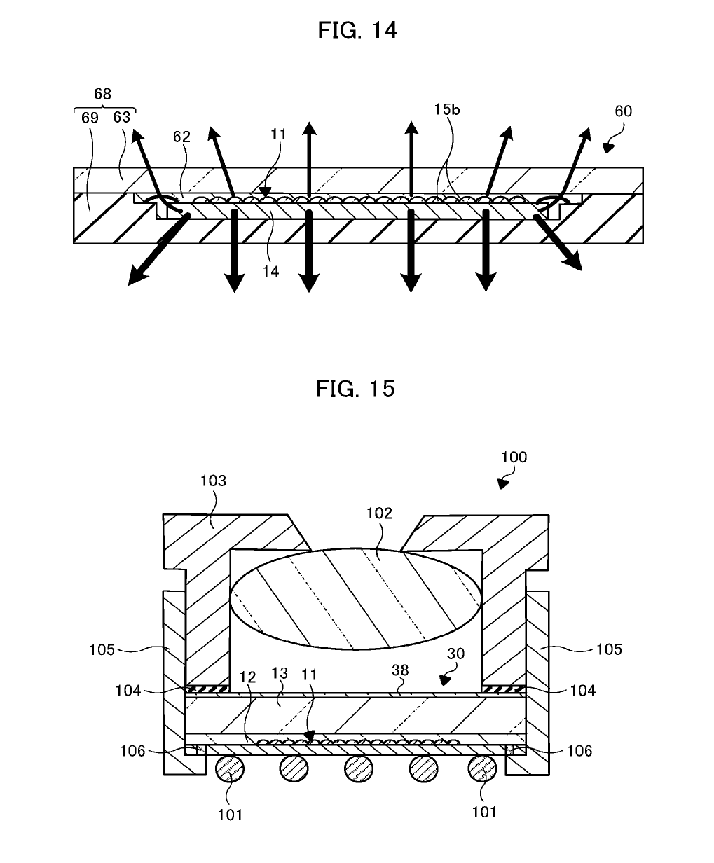

FIG. 14 is a cross-sectional diagram illustrating a heat dissipation function of the solid-state imaging device 60 having the above-described configuration and corresponding to FIG. 12. In the solid-state imaging device 60 according to the embodiment, in the case where the sensor substrate 11 dissipates heat, as illustrated by the arrows in the figure, the heat is dissipated through a semiconductor substrate 14 of the sensor substrate 11 and the housing 69 of the package 68 downwards from the solid-state imaging device 60. Furthermore, as indicated by the arrows in the same figure, the heat dissipated from the sensor substrate 11 is also dissipated to the transparent resin layer 62 which is in contact with the main surface of the sensor substrate 11 including the surface of the microlens array configured with a plurality of microlenses 15b. The heat dissipated to the transparent resin layer 62 is dissipated through the transparent substrate 63 of the package 68 upwards from the solid-state imaging device 60. By doing so, in the solid-state imaging device 60 according to the embodiment, the heat dissipation path of the heat generated from the sensor substrate 11 can be increased.

In the solid-state imaging device 60 according to the sixth embodiment and the manufacturing method therefor described heretofore, for the same reason as that of the solid-state imaging device 10 according to the first embodiment and the manufacturing method therefor, the heat dissipation property and the sensitivity are improved. Therefore, it is possible to provide a solid-state imaging device having improved imaging characteristics and a manufacturing method therefor. In addition, similarly to the solid-state imaging device 10 according to the first embodiment and the manufacturing method therefor, the warping of the sensor substrate 11 can be suppressed, and the solid-state imaging device 60 according to the sixth embodiment can be easily manufactured.

### Application Example

The solid-state imaging devices 10, 20, 30, 40, and 50 according to the first to fifth embodiments can be applied to, for example, a compact-sized camera module which is mounted in a compact-sized electronic device such as a mobile phone. Hereinafter, as an application example of solid-state imaging devices 10, 20, 30, 40, and 50 according to the first to fifth embodiments, a camera module to which the solid-state imaging device 30 according to the third embodiment is applied will be described.

FIG. 15 is a cross-sectional diagram illustrating a camera module to which the solid-state imaging device 30 according to the third embodiment is applied. In the camera module 100 illustrated in FIG. 15, a plurality of solder balls 101 as external terminals are disposed on the bottom surface of the solid-state imaging device 30 (on the bottom surface of the sensor substrate 11). In addition, each solder ball 101 is electrically connected to the light-receiving unit (not shown in FIG. 15) of the sensor substrate 11 through a through-hole electrode 106 penetrating the sensor substrate 11.

In addition, a lens holder 103 including inside a lens 102 which condenses the light is provided on the top surface of the solid-state imaging device 30 (top surface of the infrared light blocking film 38 provided in the transparent substrate 13) through an adhesive 104. The lens holder 103 is a cylindrical body configured with a light-blocking resin material and is provided at an adjusted position so that the light condensed by the lens 102 forms an image in the light-receiving unit of the solid-state imaging device 30.

Furthermore, the solid-state imaging device 30 is covered with a metal shield 105 having a function of blocking an electromagnetic wave. The shield 105 has a cylindrical shape and is provided so that a lower end portion thereof is in contact with the bottom surface of the sensor substrate 11 and an upper end portion thereof is fixed to an outer circumferential surface of the lens holder 103.

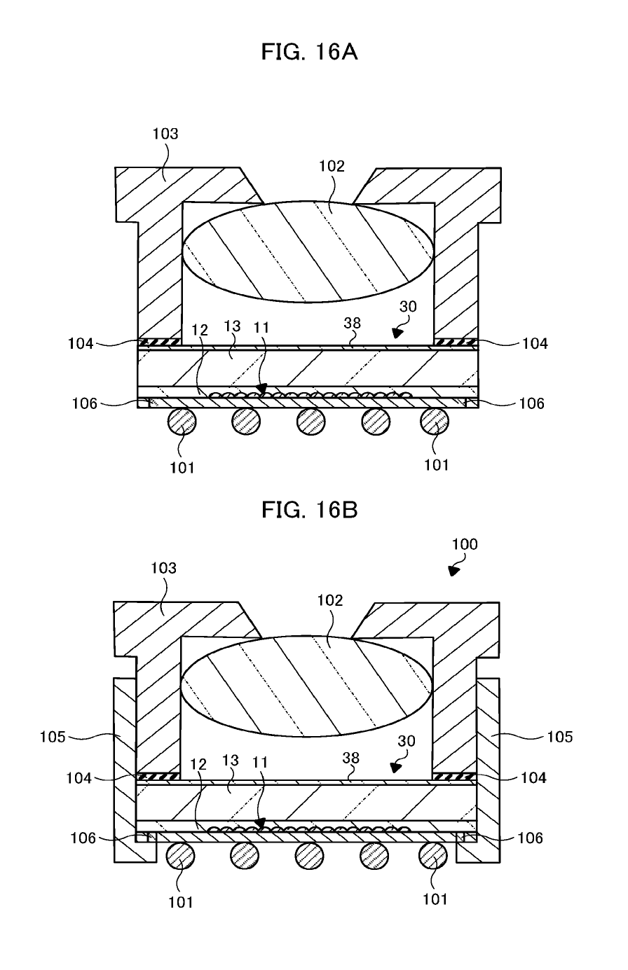

FIGS. 16A and 16B are cross-sectional diagrams illustrating a method of assembling the camera module 100 and corresponding to FIG. 15. Herein, the method of assembling the camera module 100 illustrated in FIG. 15 will be described with reference to FIGS. 16A and 16B.

First, as illustrated in FIG. 16A, a plurality of the solder balls 101 are formed on the bottom surface of the solid-state imaging device 30 (bottom surface of the sensor substrate 11). In addition, the adhesive 104 is formed on the top surface of the solid-state imaging device 30 (top surface of the infrared light blocking film 38 provided in the transparent substrate 13) in a ring shape along the outer circumference of the top surface thereof, and the cylindrical lens holder 103 is disposed on the adhesive 104. After that, the position of the lens holder 103 in the up/down direction is adjusted, and the adhesive 104 is cured. By doing so, the lens holder 103 is fixed on the solid-state imaging device 30.

Next, as illustrated in FIG. 16B, for example, the adhesive (not shown) is formed on the outer circumferential surface of the lens holder 103, and the cylindrical shield 105 is disposed so that the lower end portion thereof is in contact with the bottom surface of the solid-state imaging device 30 and the upper end portion thereof is in contact with the adhesive on the outer circumferential surface of the lens holder 103. After that, by curing the adhesive, the shield 105 is fixed to the lens holder 103, so that the camera module 100 illustrated in FIG. 15 can be assembled.

According to the camera module 100, since the solid-state imaging device 30 having excellent imaging characteristics is applied, imaging can be performed with better performance.

While certain embodiments have been described, these embodiments have been presented byway of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a sensor substrate including a microlens;
a transparent resin layer provided so as to be in contact with a main surface of the sensor substrate including a surface of the microlens; and
a transparent substrate disposed on a top surface of the transparent resin layer,
wherein a thermal conductivity of the transparent resin layer is higher than that of air, and
a refractive index of the transparent resin layer is lower than that of the microlens and is equal to or lower than that of the transparent substrate.

2. The solid-state imaging device according to claim 1, wherein the sensor substrate, the transparent resin layer, and the transparent substrate are equal to each other in terms of size.

3. The solid-state imaging device according to claim 1, wherein the transparent substrate is in contact with only the top surface of the transparent resin layer.

4. The solid-state imaging device according to claim 1, wherein the transparent resin layer has a lamination structure of a plurality of resin layers.

5. The solid-state imaging device according to claim 4,
wherein the transparent resin layer is configured to include:
a first resin layer provided so as to be in contact with the main surface of the sensor substrate including the surface of the microlens; and
a second resin layer provided so as to be in contact with a top surface of the first resin layer,
when the thermal conductivities of the air is denoted by Kair, the first resin layer is denoted by Kr1, and the second resin layer is denoted by Kr2, the first resin layer and the second resin layer satisfy relationships of Kair<Kr1 and Kair<Kr2, and
when the refractive indexes of the microlens is denoted by Nm, the transparent substrate is denoted by Ng, the first resin layer is denoted by Nr1, and the second resin layer is denoted by Nr2, the first resin layer and the second resin layer satisfy relationships of Nr1≦Ng, Nr1<Nm, and Nr2<Nm.

6. The solid-state imaging device according to claim 5, wherein the first resin layer and the second resin layer further satisfy a relationship of Nr1≦Nr2.

7. The solid-state imaging device according to claim 5, wherein the top surface of the first resin layer has a substantially planar shape.

8. The solid-state imaging device according to claim 5, wherein the transparent substrate is in contact with only a top surface of the second resin layer.

9. The solid-state imaging device according to claim 4, wherein the sensor substrate, the transparent resin layer, and the transparent substrate are equal to each other in terms of size.

10. The solid-state imaging device according to claim 1, further comprising an infrared light blocking film provided on a top surface of the transparent substrate.

11. The solid-state imaging device according to claim 1, wherein the transparent substrate is an infrared light blocking glass which transmits visible light and blocks infrared light.

12. The solid-state imaging device according to claim 1, wherein the transparent resin layer transmits visible light and blocks infrared light.

13. A camera module comprising:
a solid-state imaging device receiving light;
a lens holder provided on a top surface of the solid-state imaging device, the lens holder having a lens which condenses the light to the solid-state imaging device in the lens holder; and
a shield provided to cover a periphery of the lens holder,
wherein the solid-state imaging device includes:
a sensor substrate including a pixel which has a microlens and receives the light;
a transparent resin layer provided so as to be in contact with a main surface of the sensor substrate including a surface of the microlens;
a transparent substrate disposed on a top surface of the transparent resin layer; and
an infrared light blocking film provided on a top surface of the transparent substrate,
wherein a thermal conductivity of the transparent resin layer is higher than that of air, and
a refractive index of the transparent resin layer is lower than that of the microlens and is equal to or lower than that of the transparent substrate.

14. A method for manufacturing a solid-state imaging device, comprising:
forming a plurality of light-receiving units, each of which includes a microlens, on a main surface of a semiconductor wafer;
forming a transparent resin layer and a transparent substrate in this order on the main surface of the semiconductor wafer including surfaces of the plurality of the microlenses, wherein a thermal conductivity of the transparent resin layer is higher than that of air, and a refractive index of the transparent resin layer is lower than that of the microlens and is equal to or lower than that of the transparent substrate; and
cutting the semiconductor wafer, the transparent resin layer, and the transparent substrate corresponding to a space between the plurality of the light-receiving units.

15. The method for manufacturing a solid-state imaging device according to claim 14, wherein the transparent substrate is formed so as to be in contact with only a top surface of the transparent resin layer.

16. The method for manufacturing a solid-state imaging device according to claim 14, wherein, by forming a first resin layer so as to be in contact with the main surface of the semiconductor wafer including the surfaces of the plurality of the microlenses, and by forming a second resin layer on a top surface of the first resin layer, the transparent resin layer is formed so as to be in contact with the main surface of the semiconductor wafer including the surfaces of the plurality of the microlenses.

17. The method for manufacturing a solid-state imaging device according to claim 16,
wherein, when the thermal conductivities of the air is denoted by Kair, the first resin layer is denoted by Kr1, and the second resin layer is denoted by Kr2, the first resin layer and the second resin layer satisfy relationships of Kair<Kr1 and Kair<Kr2, and
when the refractive indexes of the microlens is denoted by Nm, the transparent substrate is denoted by Ng, the first resin layer is denoted by Nr1, and the second resin layer is denoted by Nr2, the first resin layer and the second resin layer satisfy relationships of Nr1≦Ng, Nr1<Nm, and Nr2<Nm.

18. The method for manufacturing a solid-state imaging device according to claim 17, wherein the first resin layer and the second resin layer further satisfy a relationship of Nr1≦Nr2.

19. The method for manufacturing a solid-state imaging device according to claim 16, wherein the first resin layer is formed so that the top surface of the first resin layer has a substantially planar shape.

20. The method for manufacturing a solid-state imaging device according to claim 16, wherein the transparent substrate is formed to be in contact with only a top surface of the second resin layer.
